(19) United States
(12) Patent Application Publication
(10) Pub. No.: US 2002/0106900 A1
(43) Pub. Date: Aug. 8, 2002

(54) Polishing slurry for the chemical-mechanical polishing of metal and dielectric structures

(76) Inventors: Kristina Vogt, Koln (DE); Gerd Passing, Koln (DE); Ming-Shih Tsai, Kaohsiung (TW)

Correspondence Address: BAYER CORPORATION, PATENT DEPARTMENT, 100 BAYER ROAD, PITTSBURGH, PA, 15205, US

(21) Appl. No.: 09/998,560

(22) Filed: Nov. 29, 2001

(30) Foreign Application Priority Data
Dec. 4, 2000 (DE) 10060343.2

(51) Int. Cl. H01L 21/461; H01L 21/302; H01L 21/311

(52) U.S. Cl. 438/694

(57) ABSTRACT

The invention relates to a polishing slurry for the chemical-mechanical polishing of metal and metal/dielectric structures, containing from about 2.5 to about 70% by volume of a silica sol which contains 15 to 40% by weight of SiO₂ particles and is stabilized by H⁺ or K⁺ ions, wherein the SiO₂ particles have a mean particle size of less than 300 nm, from about 6 to about 10% by volume of hydrogen peroxide and a base in a quantity which is appropriate to set the pH (22° C.) of the polishing slurry to from about 5 to about 1.5, has a Ta removal rate of >300 Å/min and an improved selectivity. Method for making and using such a slurry.

### BACKGROUND OF THE INVENTION

The present invention relates to a polishing slurry for the chemical-mechanical polishing (CMP) of metal and dielectric structures, to a method for its preparation and to its use.

What is known as the Cu damascene process is being increasingly used for the fabrication of integrated circuits (ICs) (Microchip Fabrication: A Practical Guide to Semiconductor Processing, Peter Van Zant, 4th ed., McGraw-Hill, 2000, pp 401-403 and 302-309 and Copper CMP: A Question of Tradeoffs, Peter Singer, Semiconductor International, Verlag Cahners, May 2000, pp 73-84). In this process, it is necessary for a Cu layer to be removed by chemical-mechanical means using a polishing slurry (known as the Cu-CMP process), in order to fabricate the Cu interconnects. The finished Cu interconnects are embedded in a dielectric. There is a barrier layer between Cu and the dielectric. The state of the art for the Cu-CMP process is a two-step process, i.e. the Cu layer is firstly polished with a polishing slurry which ensures a high removal of Cu. Then, a second polishing slurry is used, in order to produce the final planar surface with the brightly polished dielectric and the embedded interconnects. A wafer is a polished disk of silicon on which integrated circuits are constructed.

For the first polishing step, a highly selective polishing slurry is used, i.e. the removal rate for Cu is as high as possible, while that for the material of the barrier layer below is as low as possible. The polishing process is stopped automatically as soon as the barrier layer under the Cu is exposed. Since the complete removal of Cu residues on the barrier layer takes some time (known as over polishing), at locations where the embedded Cu interconnects are situated in the dielectric, during this period the Cu of the interconnect continues to be removed to a considerable extent. This effect is known as dishing. Depending on the particular design, a polishing slurry which is selective or non-selective with respect to the materials which are to be polished, namely Cu, barrier layer and dielectric, is used for the second polishing step.

When using a non-selective polishing slurry, i.e. with a removal rate which is approximately identical for Cu, barrier layer and dielectric, the entire wafer surface is planarized by the polishing process, including the dishing effect on the surface of the Cu interconnects, which has been caused during the Cu polishing in the first polishing step. With this arrangement, part of the dielectric layer has to be sacrificed, which represents a drawback in view of the need to deposit relatively thick dielectric and Cu layers. The critical point when using the non-selective polishing slurry is that the polishing slurry must have a planarizing effect which is identical for all three materials which are to be polished. Moreover, the Cu interconnects produced must have a minimum thickness, i.e., there must not be too much of the dielectric layer and the Cu conductor tracks sacrificed, and this has to be controlled during the polishing process.

When using a selective polishing slurry, the removal rate for the barrier layer is higher than that of the Cu. In this arrangement, the dishing of the Cu interconnects is reduced by the targeted removal of the barrier layer. The loss of dielectric and with it the Cu interconnect layer thickness are therefore lower. Corresponding examples are disclosed in WO 00/00567 and WO 99/64527. The examples cite polishing slurries with selectivities for Cu:Ta:dielectric (in this case a SiO₂, also referred to as oxide) of 1:4.5: and 1:1.6:4. The polishing slurry which is known from WO 99/64527 results in very considerable removal of the oxide as soon as the barrier layer has been polished away and therefore to an uneven wafer surface. The effect known as oxide erosion is even intensified. The term “oxide erosion” is described in Copper CMP: A Question of Tradeoffs, Peter Singer, Semiconductor International, Verlag Cahners, May 2000, pp 73-84. A selectivity ratio for Cu:Ta:oxide of 1:4.5:2, with which the drawbacks described are avoided, is only achieved with the polishing slurry containing aluminium oxide as abrasive which is described in WO 00/00567, Example 3, No. 3. A drawback of this polishing slurry is the low removal rate for the barrier layer comprising Ta of 300 Å/min, which slows the production process, and the high hardness of the aluminium oxide, which leads to increased amounts of scratches on the wafer surface (Chemical Mechanical Planarization of Microelectronic Materials, J. M. Steigerwald, S. P. Murarka, R. J. Gutmann, John Wiley & Sons, Inc. 1997, pp 42-43).

The polishing slurries which are listed in the examples of WO 99/64527 have the following removal rates (also known as RR for short) and selectivities:

TABLE 1

| | | H₂O₂/ | H₂O₂/ | | | | | |
|---|---|---|---|---|---|---|---|---|
| Example | | % by | % by | | RR | RR | RR | Selectivity |
| (Table) | Specimen | weight | volume | pH | Cu | Ta | SiO₂ | Cu:Ta:SiO₂ |
| 3 | 3 | 2 | 1.38 | 2.5 | 866 | 372 | — | 1:0.43:- |
| 3 | 4 | 2 | 1.38 | 6 | 256 | 312 | — | 1:1.22:- |
| 3 | 2 | 2 | 1.38 | 10.5 | 314 | 495 | 1261 | 1:1.58:4.02 |

Abrasives used in polishing slurries are, for example, aluminium oxide (WO 00/00567 and WO 99/47618). WO 99/67056 uses a silica sol which is modified with aluminate ions and is stabilized with Na ions. Na ions in the liquid phase of polishing slurries for the chemical-mechanical polishing of integrated circuits are generally undesirable. WO 00/24842 uses what is known as pyrogenic silica, and WO 99/64527 uses silica sol. TiO₂ is mentioned in WO 99/64527.

Moreover, further additives are used in order to increase the removal rates of the metals or to set the selectivity of the polishing slurry. In this respect, oxidizing agents, carboxylic acids and complex-forming agents are known. It is known from WO 99/64527 and WO 99/67056 that silica sols in a basic medium bring about high oxide removal rates, which is the state of the art for pure oxide polishing. WO 99/64527 adds polyvinylpyrrolidones (PVPs) to the polishing slurry, in order to reduce the oxide removal rate.

The polishing slurries mentioned have the drawback, however, that the selectivities, in particular that of Cu:oxide, are adjusted by adding, for example, film-forming agents or organic compounds, and the Cu:oxide selectivity which is predetermined by the abrasive and pH is unsuitable.

All the polishing slurries mentioned contain H₂O₂ as oxidizing agent, in order to increase the removal rates of the metals.

The term “metal” comprises the elements W, Al, Cu, Ru, Ta, Ti, Pt and Ir and/or their alloys, nitrides, carbides, oxides, carbonitrides, oxynitrides, oxycarbides and oxycarbonitrides.

The term “dielectric” encompasses organic and inorganic dielectrics. Examples of organic dielectrics are dialectric resins known by the trademark SiLK™ produced by Dow Chemical Company, polyimides, fluorinated polyimides, diamond-like carbons, polyarylethers, polyarylenes, parylene N, cyclotenes, polynorbonenes and tetrafluoroethylene (Teflon®). Inorganic dielectrics are based, for example, on SiO₂ glass as the principal constituent. Fluorine, phosphorus and/or boron compounds may be present as additional constituents. Conventional designations for these dielectrics are, for example, FSG, PSG, BSG or BPSG, where SG represents spin-on glass. Various fabrication methods are known for the fabrication of these layers (Peter Van Zant, 4th Ed., McGraw-Hill, 2000, pp 363-376 and pp 389-391). Moreover, silsesquioxanes (HSQ, MSQ) are known as dielectrics which are highly polymerized and are close to the inorganic state.

The term “barrier layer” encompasses layers of Ta, TaSi, TaN, TaSiN, Ti, TiN, WN, WSiN, SiC, silicon oxynitride, silicon oxycarbide, silicon oxycarbonitride, Si₃N₄ and/or silicon oxide.

Therefore, the object of the invention was to provide a polishing slurry with a Ta removal rate of >300 Å/min, with a Cu:Ta selectivity of 1:2 or greater and a Cu:dielectric selectivity of 1:1 or greater, the removal rate of the Ta being ≧1.15 times the removal rate of a dielectric that can be polished.

Surprisingly, it has now been found that this object is achieved with a polishing slurry which contains a silica sol as abrasive, an oxidizing agent and a base.

### SUMMARY OF THE INVENTION

The invention relates to a polishing slurry comprising (a) from about 2.5 to about 70% by volume of a silica sol that contains 1540% by weight of SiO₂ particles and is stabilized by H⁺ or K⁺ ions, the SiO₂ particles having a mean particle size of less than 300 nm, (b) from about 6 to about 10% by volume of hydrogen peroxide and a base in a quantity which is sufficient to set the pH of the polishing slurry at a pH ranging from about 5 to about 11.5.

The invention also relates to method comprising polishing a substrate with such a polishing slurry, in which the substrate is selected from the group consisting of Al substrates, Ru substrates, Pt substrates, Ir substrates, Cu substrates, Ta substrates, Ti substrates, Si substrates, W substrates, substrates comprising of alloys of the foregoing, nitride substrates, carbide subtrates, oxide substrates, carbonitrides subtrates, oxynitride subtrates, oxycarbide subtrates oxycarbonitrides substrates, and combinations thereof.

The invention also relates to a method for polishing a substrate with such a polishing slurry, in which the substrate is selected from the group consisting of, polyimide substrates, fluorinated polyimide substrates, diamond-like carbon substrates, polyarylether substrates, polyarylene substrates, parylene N substrates, cyclotene substrates, polynorbonene substrates, silsesquioxanes substrates and SiO₂ glass substrates.

The invention also relates to a method for preparing the above-mentioned slurry.

### DESCRIPTION OF THE FIGURES

These and other features, aspects, and advantages of the present invention will become better understood with reference to the following description and appended claims, where

FIG. 1 shows the selectivity for Ta and SiO₂ of polishing slurries according to example 1 as a function of H₂O₂ concentration.

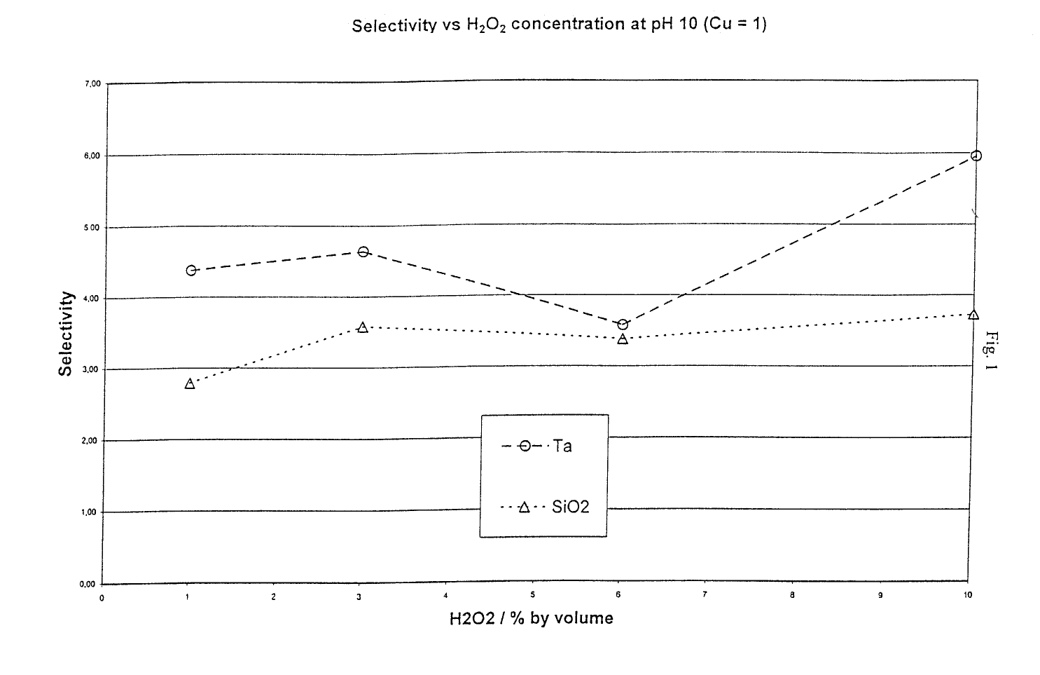

FIG. 2 shows the removal rate for Cu, Ta and SiO₂ of polishing slurries according to example 1 as a function of H₂O₂ concentration.

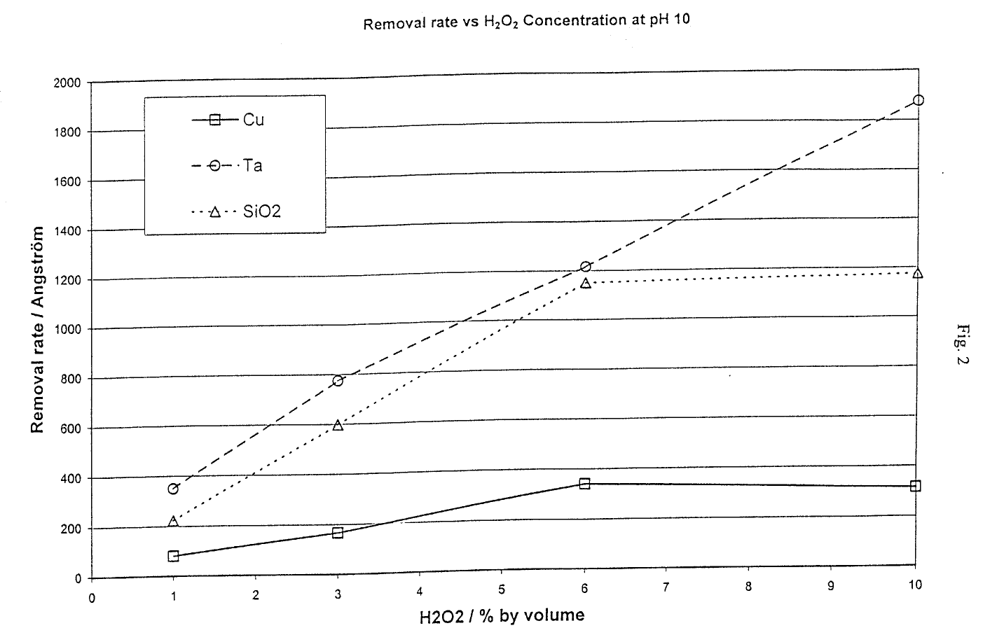

FIG. 3 shows the removal rate for Cu, Ta and SiO₂ of polishing slurries according to example 2 as a function of the pH (22° C.).

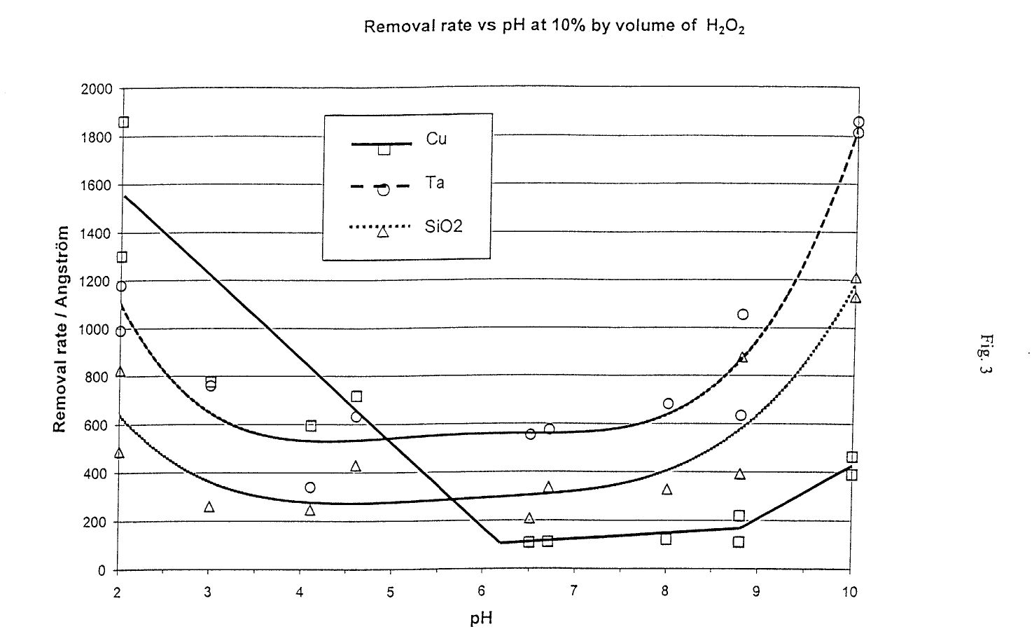

FIG. 4 shows the selectivity for Ta and SiO₂ of polishing slurries according to example 2 as a function of the pH (22° C.).

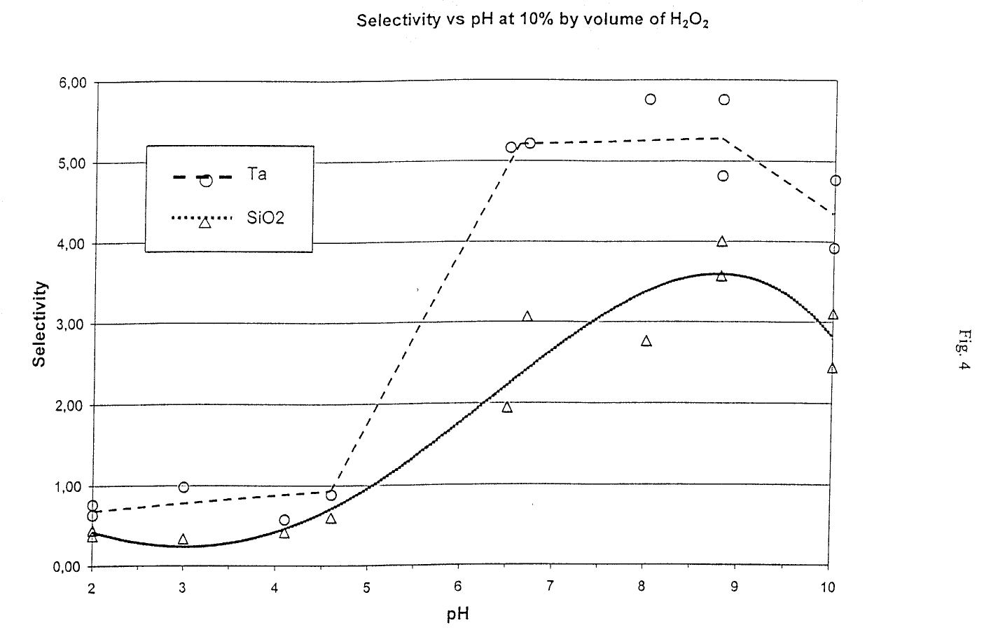

### DESCRIPTION OF THE INVENTION

As such, the invention relates to a polishing slurry for the chemical-mechanical polishing of metal and metal/dielectric structures, containing from 2.5 to 70% by volume of a silica sol which contains 15 to 40% by weight of SiO₂ and is stabilized by H⁺ or K⁺ ions and the SiO₂ particles of which have a mean particle size of less than 300 nm, 6 to 10% by volume of hydrogen peroxide and a base in a quantity which is appropriate to set the pH (22° C.) of the polishing slurry to from 5 to 11.5.

All pH values refer to pH at 22° C.

The stabilized silica sol contains preferably 20 to 35% by weight of SiO₂ particles, particularly preferred 25 to 35% by weight, more especially 28 to 32% by weight and most especially 30% by weight.

In the context of the invention, the term “silica sol” is a sol in which the colloidal SiO₂ particles are anionically stabilized. Cations in the sense of the invention are H⁺ and K⁺ ions. The primary particles of the silica sol are not aggregated. The mean particle size of the SiO₂ particles in the silica sol is less than 300 nm; the mean particle size is preferably from 50 to 90 nm. The polishing slurry according to the invention contains preferably from 1 to 21.5% by weight of SiO₂. An H⁺-stabilized silica sol has a typical pH of from 1.5 to 2.5. At higher pHs, H⁺ is replaced by K⁺, the transition being gradual. A silica sol with a pH of 7 or higher is regarded as being K⁺-stabilized.

The mean particle size is determined by ultracentrifuge.

In a preferred embodiment of the invention, the polishing slurry contains from 8 to 10% by volume of hydrogen peroxide. In view of the ease of handling, the polishing slurry according to the invention can also be prepared using dilute hydrogen peroxide solutions.

The pH of the polishing slurry of 22° C. is in the range from 5 to 11.5. The range from 6 to 10 is preferred, and the range from 7 to 9 is very particularly preferred. The polishing slurry according to the invention preferably contains potassium hydroxide as base. The pH of the polishing slurry is preferably set by adding an aqueous solution of potassium hydroxide to the silica sol. The polishing slurry according to the invention preferably contains 0.001 to 30 g/l of potassium hydroxide (100% strength).

Corrosion-prevention means for the metals, such as for example benzotriazole amine, may be added to the polishing slurry.

Moreover, complexing agents for the metals, which make the metals water-soluble, such as for example citric acid or citrates, may be added to the polishing slurry.

The invention also relates to a method for preparing a polishing slurry for the chemical-mechanical polishing of metal and metal/dielectric structures, containing 2.5 to 70% by volume of a silica sol which contains 15 to 40% by weight of SiO₂, is stabilized by H⁺ or K⁺ ions and the SiO₂ particles of which have a mean particle size of less than 300 nm, 6 to 10% by volume of hydrogen peroxide and a base in a quantity which is appropriate to set the pH (22° C.) of the polishing slurry to from 5 to 11.5, characterized in that, during the mixing of the constituents, the hydrogen peroxide is added last.

If a silica sol which is stabilized with H⁺ ions is used for the preparation of the polishing slurry, it can be converted into a K⁺-stabilized silica sol by adding KOH. After KOH has been added, the silica sol is to be agitated until an equilibrium of the anions has been established on the silica sol surface. The KOH is expediently in dissolved form.

The pH of the polishing slurry is preferably adjusted by adding potassium hydroxide to the silica sol before the hydrogen peroxide is added. After the potassium hydroxide has been added, the silica sol is to be agitated until the pH has stabilized. To prepare polishing slurries with a pH of <6, it is preferable to use a silica sol with a pH of 1.5 to 2.5. To prepare polishing slurries with a pH of >6, it is preferable to use a silica sol with a pH of 7 or higher.

The addition of the hydrogen peroxide to the silica sol preferably takes place immediately before the use of the polishing slurry, and sufficient mixing should be ensured. This can be achieved, for example, through suitable mixing nozzles. Mixing is preferably carried out directly at the location of use, i.e. just before the ready-to-use polishing slurry is applied to the polishing pad.

The invention also relates to the use of the polishing slurry according to the invention for the fabrication of semiconductors, integrated circuits and microelectro-mechanical systems.

The metals to be polished are preferably Al, Ru, Pt, Ir, Cu, Ta, Ti, Si and W and/or their alloys, nitrides, carbides, oxides, carbonitrides, oxynitrides, oxycarbides and oxycarbonitrides, it also being possible for two or more of these elements to be present.

The dielectrics to be polished are preferably SiLK™, polyimides, fluorinated polyimide, diamond-like carbons, polyarylethers, polyarylenes, parylene N, cyclotenes, polynorbonenes, Teflon, silsesquioxanes, SiO₂ glass or SiO₂ glass as the principal component with the additional components fluorine, phosphorus and/or boron.

The barrier layers to be polished are preferably layers of Ta, TaSi, TaN, TaSiN, Ti, TiN, WN, WSiN, SiC, silicon oxynitride, silicon oxycarbide, silicon oxycarbonitride, Si₃N₄ and/or silicon oxide.

The invention is further described in the following illustrative examples in which all parts and percentages are by weight unless otherwise indicated.

### EXAMPLES

The polishing experiments were carried out using the polishing machine IPEC 372M produced by Westech, USA. The polishing parameters are listed in Table 2. 150 mm wafers with coatings of Cu, Ta and SiO₂ were polished. Cu and Ta were deposited using a PVD (physical vapour deposition) process, and the SiO₂ was produced by oxidation of the Si wafer.

TABLE 2

| Polishing machine: | |
|---|---|
| IPEC 372M | |
| Working disk (polishing | 45 rpm |
| pad) rotational speed | |
| Polishing head (wafer) | 42 rpm |
| rotational speed | |
| Pressure applied | 34.5 kPa (5.0 psi) |
| Back surface pressure | 13.8 kPa (2.0 psi) |
| Slurry flow rate | 150 ml/min |
| Polishing pad | Rodel Politex Regular |
| | E. TM |

The polishing slurries were made up as follows:

30% by volume of a silica sol containing 30% by weight of SiO₂ was diluted, with stirring, with 70% by volume of a solution comprising 30% strength by weight H₂O₂ solution and distilled water. Stirring was continued for 10 minutes. The resulting SiO₂ content is 10% by weight. The amount of 1 to 10% by volume of H₂O₂ (100% strength) required for the experiments related to the overall volume, comprising silica sol, 30% strength H₂O₂ solution and distilled water. The density of the polishing slurry is approx. 1.1 g/cm³. Then, the desired pH of the polishing slurry was set using solid KOH with vigorous stirring. Stirring was continued for 60 minutes.

### EXAMPLE 1

In this series of experiments, polishing slurries comprising 1, 3, 6 and 10% by volume of H₂O₂ were prepared. Then, the specified quantities of KOH were added in order to obtain a pH (22° C.) of 10, and the mixture was stirred for one hour. After the preparation of the polishing slurries, the wafers were polished immediately. The KOH contents (100% strength, based on one liter of polishing slurry without added KOH) and the removal rates are given in Table 3.

A silica sol with a pH (22° C.) of 6.9 was used for the tests (Levasil® 50 CK/30% V2, Bayer AG, mean particle size 78-82 nm, solids content 30% by weight).

TABLE 3

| H₂O₂ concentration | | Removal rate/Å/min | | |
|---|---|---|---|---|
| % by volume | KOH/ g/L | Cu | Ta | SiO₂ |
| 1 | 3.34 | 80 | 350 | 223 |
| 3 | 6.20 | 167 | 775 | 598 |
| 6 | 19.68 | 340 | 1216 | 1150 |
| 10 | 29.89 | 315 | 1875 | 1174 |

### EXAMPLE 2

In this series of experiments, polishing slurries comprising 10% by volume of H₂O₂ were prepared. Then, the specified quantities of KOH were added, in order to obtain a pH (22° C.) of 2-10, and the mixture was stirred for one hour. Following the preparation of the polishing slurries, the wafers were polished immediately. The KOH contents (100% strength, based on one liter of polishing slurry without added KOH) and the removal rates are listed in Table 4.

A silica sol with a pH of 2.1 (Levasil® 50 CK/30% V1, Bayer AG, mean particle size 78 nm, solids content 30% by weight) was used for the tests with the pHs of 2 to 4.6.

A silica sol with a pH of 6.9 (Levasil® 50 CK/30% V2, Bayer AG, mean particle size 78-82 nm, solids content 30% by weight) was used for the tests with the pHs from 6.5 to 10.

In some instances, the polishing slurries were prepared twice. Then, immediately after the preparation of the polishing slurries, the latter were used to polish the wafers. The removal rates are listed in Table 4.

TABLE 4

| Polishing | | | | | | | |
|---|---|---|---|---|---|---|---|
| slurry | KOH | Removal rate/Å/min | | | Selectivity | | |
| PH | g/L | Cu | Ta | SiO₂ | Cu | Ta | SiO₂ |
| 2 | — | 1300 | 990 | 487 | 1 | 0.76 | 0.37 |
| 2 | — | 1861 | 1178 | 825 | 1 | 0.63 | 0.44 |
| 3 | 0.001 | 776 | 759 | 261 | 1 | 0.98 | 0.34 |
| 4.1 | 0.045 | 594 | 340 | 247 | 1 | 0.57 | 0.42 |
| 4.6 | 0.12 | 717 | 632 | 430 | 1 | 0.88 | 0.60 |
| 6.5 | 0.18 | 107 | 552 | 208 | 1 | 5.16 | 1.94 |
| 6.7 | 0.24 | 110 | 573 | 337 | 1 | 5.21 | 3.06 |
| 8 | 2.4 | 119 | 681 | 328 | 1 | 5.76 | 2.76 |
| 8.8 | 7.1 | 110 | 633 | 393 | 1 | 5.75 | 3.57 |
| 8.8 | 7.2 | 219 | 1054 | 877 | 1 | 4.81 | 4.00 |
| 10 | 29.25 | 390 | 1859 | 1211 | 1 | 4.77 | 3.11 |
| 10 | 29.89 | 463 | 1814 | 1129 | 1 | 3.92 | 2.44 |

### COMPARATIVE EXAMPLE 1

In this experiment, a polishing slurry comprising 10% by volume of H₂O₂ was prepared. The solids concentration was 10% by weight. Then, 13.14 g of KOH were added in order to obtain a pH at 22° C. of 10, and the mixture was stirred for one hour. After the polishing slurry had been prepared, the wafers were polished immediately. The removal rates and the selectivities are listed in Table 5.

A pyrogenic silica which is dispersed in water, with a pH of 11 at 22° C., was used for the experiments. The solids content was 25% by weight (SS 25 produced by Cabot, USA).

TABLE 5

| Removal rate/Å/min | | | Selectivity | | |
|---|---|---|---|---|---|
| Cu | Ta | SiO₂ | Cu | Ta | SiO₂ |
| 514 | 489 | 1500 | 1 | 0.95 | 2.92 |

### COMPARATIVE EXAMPLE 2

In this experiment, a polishing slurry comprising 10% by volume of H₂O₂ was prepared. The solids concentration was 3% by weight. Then, KOH was added, in order to obtain a pH of 10 at 22° C. Moreover, 0.001 M benzotriazole amine was added to the polishing slurry. The mixture was stirred for one hour. After the polishing slurry has been prepared, the wafers were polished immediately. The removal rates and selectivities are listed in Table 6.

A γ-aluminium oxide produced by EXTEC, USA, Type 16761, was used for the experiments. The d₅₀ value of the γ-aluminium oxide was 240 nm, the BET surface area was 100 m²/g. The γ-aluminium oxide was dispersed in the 70% by volume of water required to make up the slurry.

TABLE 6

| Removal rate/Å/min | | | Selectivity | | |
|---|---|---|---|---|---|
| Cu | Ta | SiO₂ | Cu | Ta | SiO₂ |
| 200 | 200 | 50 | 1 | 1 | 0.25 |

It can be seen from the comparative examples that polishing slurries containing pyrogenic silica or aluminium oxide as abrasive do not have the selectivities found when using the polishing slurries according to the invention.

Although the present invention has been described in detail with reference to certain preferred versions thereof, other variations are possible. Therefore, the spirit and scope of the appended claims should not be limited to the description of the versions contained therein.

What is claimed is:

1. A polishing slurry comprising:
(a) from about 2.5 to about 70% by volume of a silica sol that contains from about 15 to about 40% by weight of SiO₂ particles having a mean particle size of less than 300 nm, and
(b) from about 6 to about 10% by volume of hydrogen peroxide and a base in an amount that is sufficient to set the pH of the polishing slurry at a pH at 22° C. ranging from about 5 to about 11.5.

2. The polishing slurry of claim 1, wherein the silica sol contains from about 20 to about 35% by weight of SiO₂.

3. The polishing slurry of claim 1, wherein the silica sol contains from about 25 to about 35% by weight of SiO₂.

4. The polishing slurry of claim 1, wherein the silica sol contains from about 28 to about 32% by weight of SiO₂.

5. The polishing slurry of claim 1, wherein the silica sol contains about 30% by weight of SiO₂.

6. The polishing slurry according to claim 1, wherein the slurry contains from about 1 to about 21.5% by weight of SiO₂.

7. The polishing slurry according to claim 1, wherein the slurry contains from about 8 to about 10% by volume of hydrogen peroxide.

8. The polishing slurry according to claim 1, wherein the slurry contains potassium hydroxide as a base.

9. The polishing slurry according to claim 1, wherein the slurry has a pH at 22° C. ranging from about 6 to about 10.

10. The polishing slurry of claim 1, wherein the slurry has a Ta removal rate more than about 300 Å/min, a Cu:Ta selectivity that is more than about 1:2 and a Cu:dielectric selectivity of that is more than about 1:1 or greater, wherein the removal rate of the Ta is ≧1.15 times the removal rate of a dielectric that can be polished by the polishing slurry.

11. A polishing slurry comprising:
(a) from about 2.5 to about 70% by volume of a silica sol containing SiO2 particles, and
(b) from about 6 to about 10% by volume of hydrogen peroxide and a base in a quantity that is sufficient to set the pH of the polishing slurry at a pH at 22° C. ranging from about 5 to about 11.5,
wherein the slurry has a Ta removal rate more than about 300 Å/min, a Cu:Ta selectivity that is more than about 1:2, and a Cu:dielectric selectivity of that is more than about 1:1 or greater, wherein the removal rate of the Ta is ≧1.15 times the removal rate of a dielectric that can be polished by the slurry.

12. The slurry of claim 11, wherein the SiO₂ particles have a mean particle size of less than about 300 nm and the silica sol contains from about 15 to about 40% by weight of SiO₂.

13. The polishing slurry of claim 12, wherein the silica sol contains from about 20 to about 35% by weight of SiO₂.

14. The polishing slurry of claim 12, wherein the silica sol contains from about 25 to about 35% by weight of SiO₂.

15. The polishing slurry of claim 12, wherein the silica sol contains from about 28 to about 32% by weight of SiO₂.

16. The polishing slurry of claim 12, wherein the silica sol contains about 30 by weight of SiO₂.

17. A method comprising polishing a substrate with a polishing slurry comprising:
(a) from about 2.5 to about 70% by volume of a silica sol that contains 15 to 40% by weight of SiO₂ and is stabilized by H⁺ or K⁺ ions, the SiO₂ particles having a mean particle size of less than 300 nm, and
(b) from about 6 to about 10% by volume of hydrogen peroxide and a base in a quantity which is sufficient to set the pH of the polishing slurry at a pH at 22° C. ranging from about 5 to about 11.5,
wherein the substrate is selected from the group consisting of Al substrates, Ru substrates, Pt substrates, Ir substrates, Cu substrates, Ta substrates, Ti substrates, Si substrates, W substrates, substrates comprising of alloys of the foregoing, nitride substrates, carbide subtrates, oxide substrates, carbonitrides subtrates, oxynitride subtrates, oxycarbide subtrates oxycarbonitrides substrates, and combinations thereof.

18. A method comprising polishing a substrate with a polishing slurry comprising:
(a) from about 2.5 to about 70% by volume of a silica sol which contains 15 to 40% by weight of SiO₂ and is stabilized by H⁺ or K⁺ ions and the SiO₂ particles of which have a mean particle size of less than 300 nm, and
(b) from about 6 to about 10% by volume of hydrogen peroxide and a base in a quantity which is sufficient to set the pH of the polishing slurry at a pH at 22° C. ranging from about 5 to about 11.5,
wherein the substrate is selected from the group consisting of, polyimide substrates, fluorinated polyimide substrates, diamond-like carbon substrates, polyarylether substrates, polyarylene substrates, parylene N substrates, cyclotene substrates, polynorbonene substrates, silsesquioxanes substrates and SiO₂ glass substrates.

19. A method comprising polishing a semiconductor, an integrated circuit or a microelectro-mechanical system with a polishing slurry comprising:
(a) from about 2.5 to about 70% by volume of a silica sol that contains about 15 to 40% by weight of SiO₂ and is stabilized by H⁺ or K⁺ ions, the SiO₂ particles having a mean particle size of less than 300 nm, and
(b) from about 6 to about 10% by volume of hydrogen peroxide and a base in a quantity which is sufficient to set the pH of the polishing slurry at a pH at 22° C. ranging from about 5 to about 11.5.

20. A method for preparing a polishing slurry comprising mixing from about 2.5 to about 70% by volume of a silica sol which contains 15 to 40% by weight of SiO₂, is stabilized by H⁺ or K⁺ ions and the SiO₂ particles of which have a mean particle size of less than 300 nm, 6 to 10% by volume of hydrogen peroxide and a base in a quantity which is appropriate to set the pH at 22° C. of the polishing slurry to from 5 to 11.5,
wherein the hydrogen peroxide is added last.
